(19) United States
(12) Patent Application Publication
(10) Pub. No.: US 2026/0150211 A1
(43) Pub. Date: May 28, 2026

(54) Displays With Curved Edges

(71) Applicant: Apple Inc., Cupertino, CA (US)

(72) Inventors: Yue Cui, Los Gatos, CA (US); Brian P. Graves, San Francisco, CA (US); David A. Doyle, Needham, MA (US); Jean-Pierre S. Guillou, La Jolla, CA (US); Jung Yun Seuh, San Jose, CA (US); Ka Kuen Wan, San Jose, CA (US); Matthew P. Rao, Massapequa Park, NY (US); Ming Xu, Cupertino, CA (US); Se Hyun Ahn, Santa Clara, CA (US); Shawn R. Gettemy, San Martin, CA (US); Tyler R. Kakuda, Stockton, CA (US); Yi Qiao, San Jose, CA (US); Yifan Zhang, Palo Alto, CA (US); Ying-Chih Wang, Sunnyvale, CA (US); Yue Qu, Redwood City, CA (US); Yun Liu, Sunnyvale, CA (US)

(21) Appl. No.: 19/363,479

(22) Filed: Oct. 20, 2025

Related U.S. Application Data
(60) Provisional application No. 63/724,117, filed on Nov. 22, 2024.

(51) Int. Cl. H05K 5/03; H10K 59/80

(52) U.S. Cl. CPC H05K 5/03; H10K 59/873

(57) ABSTRACT

An electronic device may have a display overlapped by a display cover layer. Portions of the surface of the display and display cover layer may have curved profiles. For example, a display may have curved surface profiles including rounded corners having areas of compound curvature. The radius of curvature of the edge of the display panel may vary along the perimeter of the display panel. The display cover layer may have a varying thickness along the perimeter of the display panel. The thickness of the display cover layer may be different in an edge of the display cover layer than in a central portion of the display cover layer. Pixels in bent portions of the display panel may include a side mirror that asymmetrically increases off-axis luminance.

This application claims the benefit of U.S. provisional patent application No. 63/724,117, filed Nov. 22, 2024, which is hereby incorporated by reference herein in its entirety.

### FIELD

This relates generally to electronic devices, including electronic devices with displays.

### BACKGROUND

Electronic devices such as cellular telephones, tablet computers, and other electronic equipment may include displays for presenting images to a user.

If care is not taken, electronic devices with displays may not have a desired appearance or may be difficult to use satisfactorily. For example, displays may be bulky and unattractive or may not accommodate a desired electronic device shape.

### SUMMARY

An electronic device may include a display panel and a display cover layer that overlaps the display panel. The display panel may include a planar central portion, first and second opposing edge portions, third and fourth opposing edge portions that extend between the first and second opposing edge portions, and an array of pixels. The array of pixels may include at least some pixels in each one of the planar central portion and the first, second, third, and fourth edge portions and each one of the at least some pixels in the first, second, third, and fourth edge portions may include a side mirror that extends around some but not all of a periphery of that pixel. Each one of the first, second, third, and fourth edge portions may be bent away from the planar central portion.

An electronic device may include a display panel and a display cover layer that overlaps the display panel. The display panel may include a planar central portion, first and second opposing edge portions, third and fourth opposing edge portions that extend between the first and second opposing edge portions, a first rounded corner portion that is interposed between the first and third edge portions, a second rounded corner portion that is interposed between the first and fourth edge portions, a third rounded corner portion that is interposed between the second and third edge portions, a fourth rounded corner portion that is interposed between the second and fourth edge portions, and an array of pixels comprising at least some pixels in each one of the planar central portion, the first, second, third, and fourth edge portions, and the first, second, third, and fourth rounded corner portions. Each one of the first, second, third, and fourth edge portions may be bent away from the planar central portion, each one of the first, second, third, and fourth rounded corner portions may be bent away from the planar central portion, a middle of the first edge portion may have a first radius of curvature, a middle of the first rounded corner portion may have a second radius of curvature that is greater than the first radius of curvature, and a radius of curvature of the display panel may gradually increase along a perimeter of the display panel from the first radius of curvature to the second radius of curvature.

An electronic device may include a display panel, a display cover layer that overlaps the display panel, an anti-reflection layer on an outer surface of the display cover layer, and a circular polarizer that is interposed between the display panel and the display cover layer. The display panel may include a planar central portion, first and second opposing edge portions, third and fourth opposing edge portions that extend between the first and second opposing edge portions, and an array of pixels. Each one of the first, second, third, and fourth edge portions may be bent away from the planar central portion. The array of pixels may include at least some pixels in each one of the planar central portion and the first, second, third, and fourth edge portions. The circular polarizer may include a polarizing layer, a substrate, an adhesive layer, and a quarter wave plate. The substrate may be interposed between the polarizing layer and the adhesive layer, the adhesive layer may be interposed between the substrate and the quarter wave plate and the adhesive layer may have a refractive index between 1.50 and 1.55.

### BRIEF DESCRIPTION OF THE DRAWINGS

FIG. 1 is a schematic diagram of an illustrative electronic device in accordance with some embodiments.

FIG. 2 is a top view of an illustrative electronic device in accordance with some embodiments.

FIG. 3 is a cross-sectional side view of an illustrative electronic device in accordance with some embodiments.

FIG. 4 is a cross-sectional side view of an illustrative planar portion of a display cover layer and pixel array in accordance with some embodiments.

FIG. 5 is a cross-sectional side view of an illustrative curved portion of a display cover layer and pixel array in accordance with some embodiments.

FIG. 6 is a cross-sectional side view of an illustrative sidewall portion of an electronic device in accordance with some embodiments.

FIG. 7 is a perspective view of an illustrative corner portion of an electronic device in accordance with some embodiments.

FIG. 8 is a top view of an illustrative display with a rectangular footprint with rounded corners in accordance with some embodiments.

FIGS. 9A-9C are cross-sectional side views of the illustrative display of FIG. 8 showing varying radius of curvature along the edge of the display in accordance with some embodiments.

FIG. 10A is a graph of radius of curvature of an illustrative display panel as a function of position along the perimeter of the display in accordance with some embodiments.

FIG. 10B is a graph of maximum display cover layer thickness of an illustrative display cover layer as a function of position along the perimeter of the display in accordance with some embodiments.

FIG. 11 is a cross-sectional side view of an illustrative display with a display cover layer having an edge thickness that is different than a central thickness in accordance with some embodiments.

FIG. 12 is a cross-sectional side view of an illustrative display with bent edges, an anti-reflective layer, and a circular polarizer in accordance with some embodiments.

FIG. 13 is a cross-sectional side view of an illustrative circular polarizer in accordance with some embodiments.

FIG. 14 is a cross-sectional side view of an illustrative display with bent edges in accordance with some embodiments.

FIG. 15A is a cross-sectional side view of an illustrative pixel in a central portion of a display that includes no side mirror in accordance with some embodiments.

FIG. 15B is a cross-sectional side view of an illustrative pixel in a bent edge of a display that includes an asymmetric side mirror in accordance with some embodiments.

FIGS. 16A-16I are top views of illustrative pixels from different portions of the display of FIG. 8 in accordance with some embodiments.

### DETAILED DESCRIPTION

Electronic devices may be provided with displays. The displays may have planar surfaces and curved surfaces. For example, a display may have a planar central portion surrounded by bent edges. The bent edges may have curved surface profiles. Arrangements in which displays exhibit compound curvature may also be used. Electronic devices having displays with curved surfaces may have an attractive appearance, may allow the displays to be viewed from a variety of different angles, and may include displays with a borderless or nearly borderless configuration.

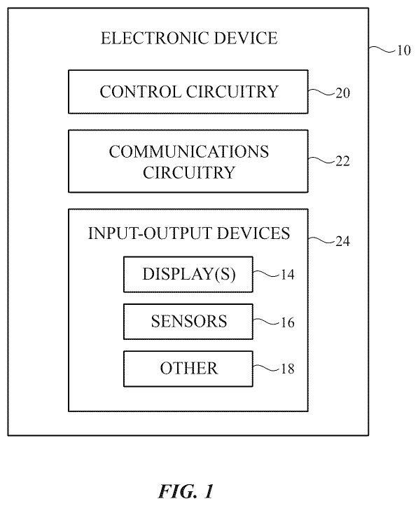

A schematic diagram of an illustrative electronic device having a display with curved surface portions is shown in FIG. 1. Device 10 may be a cellular telephone, a tablet computer, a laptop computer, a wristwatch device, a head-mounted device, or other wearable device, a television, a stand-alone computer display or other monitor, a computer display with an embedded computer (e.g., a desktop computer), a system embedded in a vehicle, kiosk, or other embedded electronic device, a media player, or other electronic equipment.

Device 10 may include control circuitry 20. Control circuitry 20 may include storage and processing circuitry for supporting the operation of device 10. The storage and processing circuitry may include storage such as nonvolatile memory (e.g., flash memory or other electrically-programmable-read-only memory configured to form a solid state drive), volatile memory (e.g., static or dynamic random-access-memory), etc. Processing circuitry in control circuitry 20 may be used to gather input from sensors and other input devices and may be used to control output devices. The processing circuitry may be based on one or more microprocessors, microcontrollers, digital signal processors, baseband processors and other wireless communications circuits, power management units, audio chips, application specific integrated circuits, etc.

To support communications between device 10 and external equipment, control circuitry 20 may communicate using communications circuitry 22. Circuitry 22 may include antennas, radio-frequency transceiver circuitry, and other wireless communications circuitry and/or wired communications circuitry. Circuitry 22, which may sometimes be referred to as control circuitry and/or control and communications circuitry, may support bidirectional wireless communications between device 10 and external equipment over a wireless link (e.g., circuitry 22 may include radio-frequency transceiver circuitry such as wireless local area network transceiver circuitry configured to support communications over a wireless local area network link, near-field communications transceiver circuitry configured to support communications over a near-field communications link, cellular telephone transceiver circuitry configured to support communications over a cellular telephone link, or transceiver circuitry configured to support communications over any other suitable wired or wireless communications link). Wireless communications may, for example, be supported over a Bluetooth® link, a WiFi® link, a 60 GHz link or other millimeter wave link, a cellular telephone link, or other wireless communications link. Device 10 may, if desired, include power circuits for transmitting and/or receiving wired and/or wireless power and may include batteries or other energy storage devices. For example, device 10 may include a coil and rectifier to receive wireless power that is provided to circuitry in device 10.

Device 10 may include input-output devices such as devices 24. Input-output devices 24 may be used in gathering user input, in gathering information on the environment surrounding the user, and/or in providing a user with output. During operation, control circuitry 20 may use sensors and other input devices in devices 24 to gather input and can control output devices in devices 24 to provide desired output.

Devices 24 may include one or more displays such as display(s) 14. An output device such as display 14 may be an organic light-emitting diode (OLED) display, a liquid crystal display, an electrophoretic display, an electrowetting display, a plasma display, a microelectromechanical systems display, a display having a pixel array formed from crystalline semiconductor light-emitting diode dies (sometimes referred to as microLEDs), and/or other display. Display 14 may have an array of pixels configured to display images for a user. The display pixels may be formed on a substrate such as a flexible substrate (e.g., display 14 may be formed from a flexible display panel). Conductive electrodes for a capacitive touch sensor in display 14 and/or an array of indium tin oxide electrodes or other transparent conductive electrodes overlapping display 14 may be used to form a two-dimensional capacitive touch sensor for display 14 (e.g., display 14 may be a touch sensitive display).

Sensors 16 in input-output devices 24 may include force sensors (e.g., strain gauges, capacitive force sensors, resistive force sensors, etc.), audio sensors such as microphones, touch and/or proximity sensors such as capacitive sensors (e.g., a two-dimensional capacitive touch sensor integrated into display 14, a two-dimensional capacitive touch sensor overlapping display 14, and/or a touch sensor that forms a button, trackpad, or other input device not associated with a display), and other sensors. If desired, sensors 16 may include optical sensors such as optical sensors that emit and detect light, ultrasonic sensors, optical touch sensors, optical proximity sensors, and/or other touch sensors and/or proximity sensors, monochromatic and color ambient light sensors, image sensors, fingerprint sensors, temperature sensors, sensors for measuring three-dimensional non-contact gestures (“air gestures”), pressure sensors, sensors for detecting position, orientation, and/or motion (e.g., accelerometers, magnetic sensors such as compass sensors, gyroscopes, and/or inertial measurement units that contain some or all of these sensors), health sensors, radio-frequency sensors, depth sensors (e.g., structured light sensors and/or depth sensors based on stereo imaging devices), optical sensors such as self-mixing sensors and light detection and ranging (lidar) sensors that gather time-of-flight measurements, humidity sensors, moisture sensors, gaze tracking sensors, and/or other sensors. In some arrangements, device 10 may use sensors 16 and/or other input-output devices to gather user input (e.g., buttons may be used to gather button press input, touch sensors overlapping displays can be used for gathering user touch screen input, touch pads may be used in gathering touch input, microphones may be used for gathering audio input, accelerometers may be used in monitoring when a finger contacts an input surface and may therefore be used to gather finger press input, etc.).

If desired, electronic device 10 may include additional components (see, e.g., other devices 18 in input-output devices 24). The additional components may include haptic output devices, audio output devices such as speakers, light producing output devices such as light-emitting diodes for status indicators, light sources such as light-emitting diodes (e.g., crystalline semiconductor light-emitting diodes) that illuminate portions of a housing and/or display structure, other optical output devices, and/or other circuitry for gathering input and/or providing output. Device 10 may also include a battery or other energy storage device, connector ports for supporting wired communication with ancillary equipment and for receiving wired power, and other circuitry.

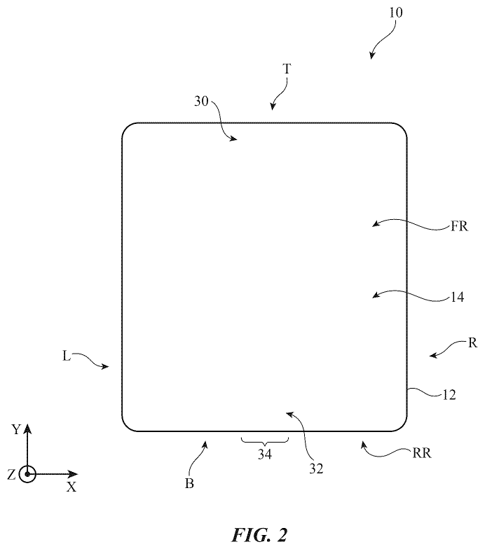

FIG. 2 is a front (plan) view of electronic device 10 in an illustrative configuration in which display 14 covers some or all of the front face FR of device 10. Opposing rear face RR of device 10 may be covered by a housing wall formed from glass, metal, polymer, and/or other materials. Rear face RR may be free of display pixels and/or may be partly or fully covered by display 14.

Device 10 may include a housing (e.g., housing 12) that forms sidewall structures for device 10 and/or internal supporting structures (e.g., a frame, midplate member, etc.). In some illustrative arrangements, sidewall portions of device 10 may be covered with portions of display 14. In the example of FIG. 2, device 10 is characterized by four peripheral edges: upper edge T, lower edge B, left edge L, and right edge R. Upper edge T and opposing lower edge B may run parallel to each other and parallel to the X axis of FIG. 2. Left edge L and opposing right edge R may run parallel to each other and parallel to the Y axis of FIG. 2. Front face FR and rear face RR may be planar (e.g., two parallel planes offset by a distance along the Z axis) and/or may include curved portions.

Touch sensor circuitry such as two-dimensional capacitive touch sensor circuitry may be incorporated into one or more display panels in device 10 as separate touch sensor panels overlapping display pixels or may be formed as part of one or more display panels in device 10. Touch sensors may be formed on front face FR, rear face RR, and/or edges (sidewall faces) T, B, R, and/or L. If desired, icons and other images for virtual buttons may be displayed by the pixels of device. For example, virtual buttons and/or other images may be displayed on front face FR, rear face RR, and/or sidewall structures in device 10 such as edges T, B, R, and/or L and may overlap touch sensor circuitry. Haptic output devices may be used to provide haptic feedback when virtual buttons are selected (as an example).

Device 10 of FIG. 2 has a rectangular outline with four rounded corners. If desired, device 10 may have other shapes. For example, device 10 may have a shape that folds and unfolds along a bend (folding) axis and may include a display that overlaps or that does not overlap the bend axis, may have a shape with an oval footprint or circular outline, may have a cubic shape, may have a pyramidal, cylindrical, or conical shape, or may have other suitable shapes. The configuration of FIG. 2 is illustrative.

If desired, openings may be formed in the surfaces of device 10. For example, a speaker port and optical windows for an ambient light sensor, an infrared proximity sensor, and a depth sensor may be formed in a region such as upper region 30 of front face FR. A finger print sensor, touch sensor button, force-sensitive button, or other sensor that operates through display 14 may be formed under the portion of display in lower region 32 on front face FR and/or other portions of front face FR and/or other external surfaces of device 10. An optional opening for a connector (e.g., a digital data connector, analog signal connector, and/or power connector) may be formed in portion 34 of the lower sidewall of device 10 running along lower edge B. This opening may be omitted when power is received wirelessly or is received through contacts that are flush with the surface of device 10 and/or when data is transferred and received wirelessly using wireless communications circuitry in circuitry 22 or through contacts that are flush with the exterior surface of device 10.

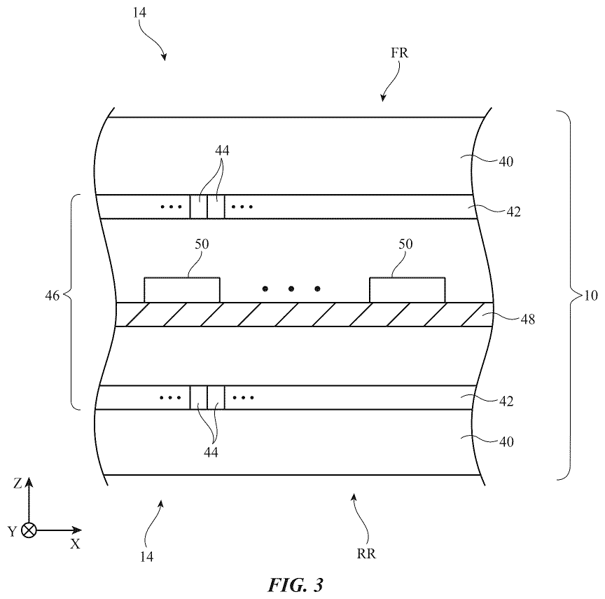

FIG. 3 is a cross-sectional side view of an illustrative electronic device. As shown in FIG. 3, display 14 may be formed on front face FR and/or rear face RR of device 10. Display 14 may include one or more transparent protective layers such as display cover layer 40. Display cover layer 40 may be formed from transparent material such as clear glass, polymer, sapphire or other crystalline material, or other transparent material. Display layers such as layers 42 may have arrays of pixels 44 that form images. The pixel arrays (e.g., layers 42) may sometimes be referred to as pixel layers, pixel array layers, displays, display structures, display layers, or display panels. For example, layers 42 may be formed from organic light-emitting diode displays. In the example of FIG. 3, device 10 has a first display 14 (or first display portion of a display panel or other display structure) formed from a first pixel array 42 on front face FR. This first pixel array is visible in the −Z direction through display cover layer 40 on front face FR. Device 10 of FIG. 3 also has a second display 14 (or second display portion of the display panel or other display structure) formed from a second pixel array 42 on rear face RF. This second pixel array is visible in the +Z direction through display cover layer 40 on rear face RR. The front and/or rear surfaces formed by display cover layer(s) 40 may be planar (as shown in FIG. 3) or may have a curved profile.

If desired, the second display 14 of device 10 may be omitted. For example, pixel array 42 on rear face RR may be omitted. In this configuration, the inner surface of layer 40 on rear face RR may be coated with a black masking material or other opaque coating and/or may be coated with colored and/or shiny structures. Coating material can be patterned to form logos, text, and other visual elements. This type of arrangement may be used to hide internal components in interior 46 of device from view from the exterior of device 10. As shown in FIG. 3, for example, device 10 may include electrical components 50 in interior 46 (e.g., integrated circuits, sensors and other input-output devices, control circuitry, display layers 42 such as organic light-emitting diode panels or other display layers, etc.). Electrical components 50 may, if desired, be mounted on printed circuits such as printed circuit 48 (e.g., flexible printed circuits and/or printed circuits formed from rigid printed circuit board material). In configurations such as these in which the lower pixel array of device 10 is omitted, the portion of device 10 on rear face RR (e.g., layer 40) may be formed from metal (e.g., a stainless steel or aluminum layer). For example, device 10 may have a rear housing wall formed from metal. Device 10 may also have housing walls formed from opaque glass, transparent glass coated with opaque materials such as ink or metal, and/or other housing wall materials.

In some configurations for device 10, an opaque material such as metal or opaque polymer may form some or all of the sidewalls of device 10. As an example, metal that forms some or all of a rear housing wall on rear face RR of device 10 may protrude upwardly along the edges of device 10 to form some or all of the sidewalls for device 10. As another example, a peripheral metal band that forms some or all of the sidewalls of device 10 may extend around the rectangular periphery of device 10 (e.g., along upper edge T, right edge R, lower edge B, and left edge L). Sidewalls may have vertically extending planar surfaces and/or may exhibit other surface profiles (e.g., curved profiles).

If desired, some or all of the sidewalls of device 10 may be formed from clear material and may overlap light-producing components. This material may, as an example, be part of display cover layers 40 of FIG. 3 (e.g., an extending piece of glass, polymer, crystalline material, or other transparent display cover layer material). Because clear layers of glass, plastic, crystalline material, and/or other clear layers of material in device 10 may enclose and protect internal device components, these outer layers of material in device 10 serve as an enclosure (housing 12) for device 10.

In configurations for device 10 in which sidewalls have transparent portions formed from extending portions of display cover layers 40 or other transparent material, the sidewalls may overlap light-emitting components. Transparent sidewalls may have planar and/or curved surfaces and may be formed from clear glass, clear polymer, transparent crystalline material such as sapphire, and/or other transparent protective material. Displays (pixel arrays), light-emitting diodes covered with diffusing material, light-emitting diodes covered with patterned masks (e.g., opaque coatings with icon-shaped openings or openings of other shapes), and/or other light-emitting devices may be placed under clear sidewalls.

During operation, light emitted from the pixels or other light-emitting components under the sidewalls may pass through the sidewalls. In arrangements in which display panels are placed under transparent sidewalls, images may be displayed through the sidewalls. The images may form parts of images being displayed on front face FR and/or rear face RR and/or may be separate images. For example, a photograph may extend across front face FR and some or all of the sidewalls of device 10 and/or a photograph may cover only front face FR while virtual buttons are displayed on the sidewalls of device 10. In arrangements in which one or more light-emitting diodes and an overlapping diffuser are placed under transparent sidewalls, diffuse light may be emitted through the sidewalls.

In addition to optional opaque housing structures such as metal housing walls or opaque walls formed from other materials, device 10 may include display cover layers 40 and other structures formed from transparent glass, transparent polymer, and/or other transparent material. These materials may surround the interior of device 10 and thereby serve as a housing for device 10 as well as serving as protective layers for pixel arrays and other light-emitting components. In the example of FIG. 3, the front surface of device 10 is formed by a planar surface of display cover layer 40 on front face FR and the rear surface of device 10 is formed by a planar surface of display cover layer 40 on rear face RR. In general, device 10 may have planar surface portions and/or curved surface portions (surface portions with curved profiles) and these portions may be formed by display cover layers, other layers formed from glass, polymer, sapphire or other crystalline material, ceramic, or other potentially transparent materials, metal, wood, or other materials.

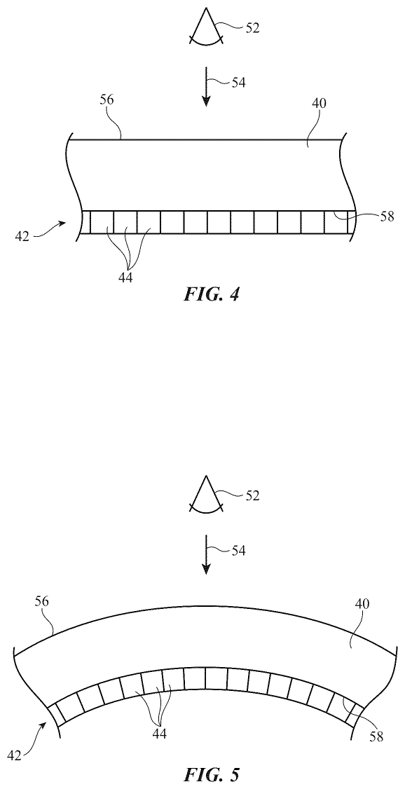

Transparent portions of device 10 may overlap pixels or other light-emitting components that emit light that is visible to a user. In the illustrative arrangements of FIGS. 4 and 5, an array of pixels 44 in layer 42 is configured to emit light that passes through display cover layer 40 for viewing by viewer 52 (e.g., in direction 54 and/or other directions from the exterior of device 10). The inner and outer surface of layers 40 (and other layers enclosing the interior of device 10) may be planar and/or curved. In the illustrative configuration of FIG. 4, outer surface 56 of layer 40 and inner surface 58 of layer 40 are planar. Inner surface 58 of FIG. 4 may be curved or partly planar and partly curved, if desired. In the illustrative configuration of FIG. 5, outer surface 56 of layer 40 is curved and inner surface 58 of layer 40 is curved. Inner surface 58 may, if desired, be planar or may have planar and curved surface profile portions.

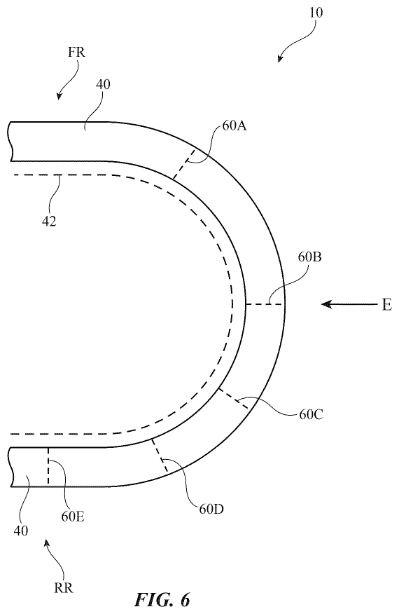

Device 10 may have upper and/or lower surfaces (e.g., external surfaces 56 on front face FR and rear face RR, respectively) that are planar and/or curved. The edges of device 10 may have sidewalls with planar and/or curved portions (e.g., surfaces with straight and/or curved profiles). As shown in FIG. 6, for example, the sidewalls of device 10 along one or more edges such as edge E of device 10 (e.g., left edge L, right edge R, upper edge T, lower edge B, and/or the corners of device 10) may have a curved outer surface.

Edge E may be transparent (e.g., the entire sidewall of device 10 may be transparent and may be formed from extended portions of upper and lower display cover layer(s)) and/or one or more portions of the curved sidewall of edge E may be opaque (e.g., formed from glass or other material that is coated with opaque material, formed from opaque polymer, formed from metal, and/or formed from other opaque structures). Opaque structures (e.g., metal housing wall portions) may extend along one or more portions of edge E (e.g., metal or other opaque material may form the portion of edge E between locations 60A and 60B, between locations 60B and 60C, between locations 60C and 60D, between locations 60D and 60E, between locations 60A and 60C, between locations 60B and 60D, between locations 60C and 60E, or between other suitable locations on edge E). There may be a single strip of metal housing material that runs around all four peripheral edges E of device 10, there may be a pair of discrete strips of metal housing material that run around all four peripheral edges E in parallel, there may be no non-glass structures on edges E, and/or there may be other suitable structures on edges E.

Display layer 42 may be formed from a single panel (e.g., a single flexible organic light-emitting diode display panel having a polyimide substrate or other flexible substrate with bent edge portions), may be formed from multiple panels (e.g., multiple panels separated from one or more gaps), may be formed from panels with slits and other openings, and/or may be formed from other types of displays. Portions of display layer 42 (e.g., all of layer 42 and/or the pixels and/or other structures of layer 42) may be omitted wherever layer 42 is overlapped by a metal portion of edge E and/or other opaque structures in edge E. For example, edge E may be formed from glass everywhere except between locations 60B and 60D. The portion of edge (sidewall) E between locations 60B and 60D may be formed from metal (as an example). In this type of scenario, no display layer 42 (or at least no pixels 44) may be overlapped by the metal and pixels 44 and display layer 42 may be present under the glass portions of edge E and/or display cover layer 40 on front face FR and/or rear face RR.

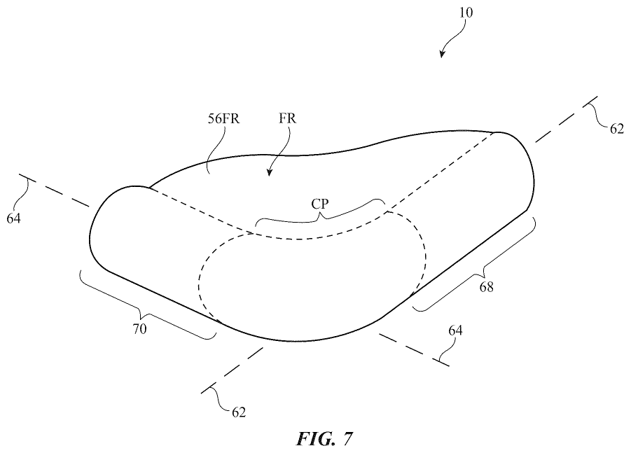

If desired, device 10 may have external surfaces with compound curvature. A perspective view of an illustrative corner portion of device 10 is shown in FIG. 7. In the example of FIG. 7, device 10 has edge portions (sidewalls) 68 and 70 with surfaces that curve about axes 62 and 64, respectively. These portions extend along the straight sides of device 10 and are characterized by curved surfaces that can be flattened into a plane without distortion (sometimes referred to as developable surfaces). At the corner of device 10, device 10 has curved surface portions CP with compound curvature (e.g., a surface that can only be flattened into a plane with distortion, sometimes referred to as a surface with Gaussian curvature). Each of the four corners of device 10 may have this arrangement, if desired.

Flexible displays such as organic light-emitting diode displays with flexible polyimide substrates or other bendable polymer substrates can be bent about axes such as axes 62 and 64 to form curved surfaces in portions 68 and 70. In compound curvature regions such as corner regions of device 10, display 14 can be formed from materials that stretch (e.g., displays formed from mesh-shaped elastomeric substrate material), may be formed from flexible displays that are patterned to create flexible strips and other structures that can be bent to cover at least part of the compound curvature regions, and/or may use optical structures (e.g., lenses, etc.) to redirect light emitted from pixels in a display to surfaces with compound curvature.

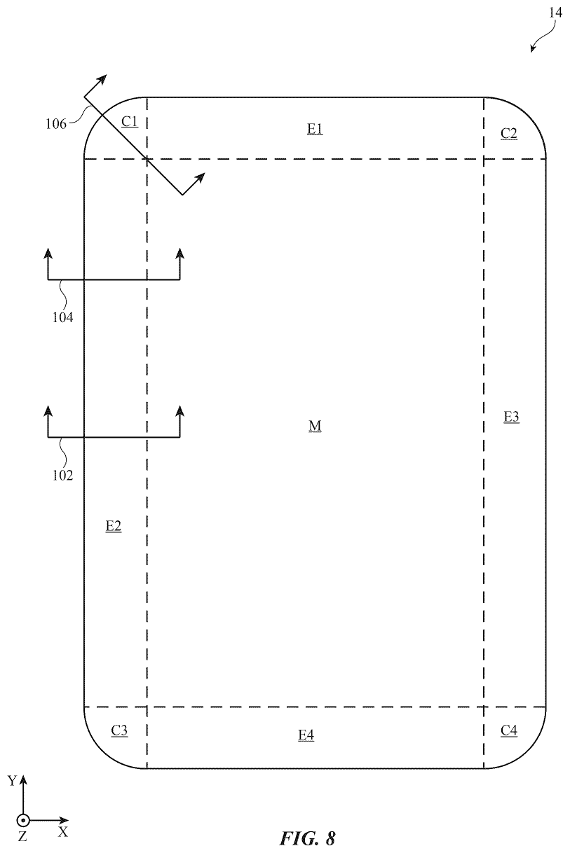

FIG. 8 is a top view of an illustrative display with curved edges and corners. As shown in FIG. 8, display 14 may have a rectangular footprint with rounded corners. The display has a central portion M (sometimes referred to as middle portion, planar portion, etc.), edge portions E1, E2, E3, and E4, and corner portions C1, C2, C3, and C4 (sometimes referred to as rounded corner portions). Display 14 includes a display cover layer 40 that overlaps a display panel 42. Herein, central portion M, edge portions E1, E2, E3, and E4, and corner portions C1, C2, C3, and C4 may be used to refer to the central, edge, and corner portions of the display, the display cover layer, and the display panel. Edge portion E1 extends parallel to the X-axis, edge portion E2 extends parallel to the Y-axis, edge portion E3 extends parallel to the Y-axis, and edge portion E4 extends parallel to the X-axis. Corner portion C1 is interposed between edge portions E1 and E2. Corner portion C2 is interposed between edge portions E1 and E3. Corner portion C3 is interposed between edge portions E2 and E4. Corner portion C4 is interposed between edge portions E3 and E4.

Central portion M may be planar. The central portion may be parallel to the XY-plane. In contrast, each one of edge portions E1, E2, E3, and E4, and corner portions C1, C2, C3, and C4 may be bent away from central portion M. Said another way, each one of edge portions E1, E2, E3, and E4, and corner portions C1, C2, C3, and C4 may be bent away from a plane that includes central portion M. Each one of edge portions E1, E2, E3, and E4, and corner portions C1, C2, C3, and C4 may be referred to as having curved surface profiles.

The outermost portion of edge E1 (e.g., on the positive Y-side of E1) may be bent downwards (e.g., in the negative Z-direction). The outermost portion of edge E2 (e.g., on the negative X-side of E2) may be bent downwards (e.g., in the negative Z-direction). The outermost portion of edge E3 (e.g., on the positive X-side of E3) may be bent downwards (e.g., in the negative Z-direction). The outermost portion of edge E4 (e.g., on the negative Y-side of E4) may be bent downwards (e.g., in the negative Z-direction). Each edge portion therefore curves about only one bend axis. The edge portions have curved surfaces that can be flattened into a plane without distortion (sometimes referred to as developable surfaces).

The outermost portion of corner C1 (e.g., on the positive Y-side and negative X-side of C1) may be bent downwards (e.g., in the negative Z-direction). The outermost portion of corner C2 (e.g., on the positive X-side and positive Y-side of C2) may be bent downwards (e.g., in the negative Z-direction). The outermost portion of corner C3 (e.g., on the negative X-side and negative Y-side of C3) may be bent downwards (e.g., in the negative Z-direction). The outermost portion of corner C4 (e.g., on the negative Y-side and positive X-side of C4) may be bent downwards (e.g., in the negative Z-direction). Each corner portion therefore curves about two bend axes. The corner portions have curved surfaces with compound curvature (e.g., a surface that can only be flattened into a plane with distortion, sometimes referred to as a surface with Gaussian curvature).

To provide display 14 with a target aesthetic appearance, the radius of curvature of display panel 42 may vary as a function of position along the perimeter of the display. In particular, the radius of curvature may be higher (with the display panel therefore being less curved) in the corner portions of the display than in the edge portions of the display. Achieving a lower radius of curvature (with the display panel being more curved) may be easier for non-compound-curved surfaces (as in edges E1, E2, E3, and E4) than in surfaces with compound curvature (as in corners C1, C2, C3, C4). The display is therefore curved by a greater amount at the edge portions than in the corner portions.

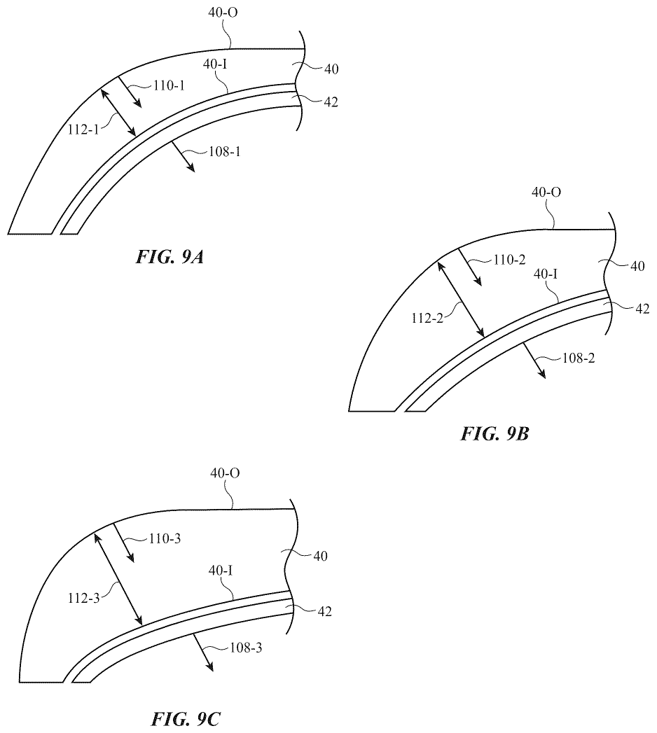

In one illustrative example, there may be a gradual change in the radius of curvature of the display panel between the middle of the edge portion of the display panel and the middle of the corner portion of the display panel. FIGS. 9A-9C show an example of this type. FIG. 9A is a cross-sectional side view of display 14 taken along line 102 in FIG. 8. FIG. 9B is a cross-sectional side view of display 14 taken along line 104 in FIG. 8. FIG. 9C is a cross-sectional side view of display 14 taken along line 106 in FIG. 8. FIG. 9A therefore shows the middle of edge portion E2 (along the perimeter of the display within the edge portion). FIG. 9C shows the middle of corner portion C1 (along the perimeter of the display within the corner portion). FIG. 9B shows a point along the perimeter of the display between the points of FIG. 9A and FIG. 9C.

As shown in FIG. 9A, display panel 42 may have a bend characterized by a radius of curvature 108-1. The display panel is overlapped by a display cover layer 40. The display cover layer conforms to the display panel. The display cover layer has an outer surface that is characterized by a radius of curvature 110-1. In FIG. 9B, display panel 42 may have a bend characterized by a radius of curvature 108-2 and display cover layer 40 has an outer surface that is characterized by a radius of curvature 110-2. In FIG. 9C, display panel 42 may have a bend characterized by a radius of curvature 108-3 and display cover layer 40 has an outer surface that is characterized by a radius of curvature 110-3.

The radius of curvature increases along the perimeter of the display from the middle of the edge portion to the middle of the corner portion. Therefore, the magnitude of radius of curvature 108-1 is less than the magnitude of radius of curvature 108-2. The magnitude of radius of curvature 108-2 is less than the magnitude of radius of curvature 108-3. In other words, the display panel becomes less bent along the perimeter of the display from the middle of the edge portion to the middle of the corner portion. The thickness of display 42 may be constant across the footprint of display 14 and the radius of curvature of the inner and outer surfaces of display panel 42 may be approximately equal.

The display cover layer, meanwhile, may have an outer surface with a constant radius of curvature along the perimeter of the display. Therefore, the magnitudes of radius of curvature 110-1, radius of curvature 110-2, and radius of curvature 110-3 are equal. Display cover layer 40 conforms to display panel 42. The inner surface 40-I therefore has a radius of curvature that is approximately equal to the radius of curvature of display panel 42. Because display cover layer 40 has an outer surface with constant radius of curvature and an inner surface that conforms to the display panel with varying curvature, display cover layer 40 has a varying thickness.

In FIG. 9A, display cover layer 40 has a maximum thickness 112-1 in a portion of the display cover layer that overlaps the bent portion of display panel 42. In FIG. 9B, display cover layer 40 has a maximum thickness 112-2 in a portion of the display cover layer that overlaps the bent portion of display panel 42. In FIG. 9C, display cover layer 40 has a maximum thickness 112-3 in a portion of the display cover layer that overlaps the bent portion of display panel 42. Maximum thickness 112-1 is less than maximum thickness 112-2 and maximum thickness 112-2 is less than maximum thickness 112-3. The display cover layer may have a uniform thickness over central portion M of the display. The uniform thickness in central portion M may be less than maximum thicknesses 112-1, 112-2, and/or 112-3.

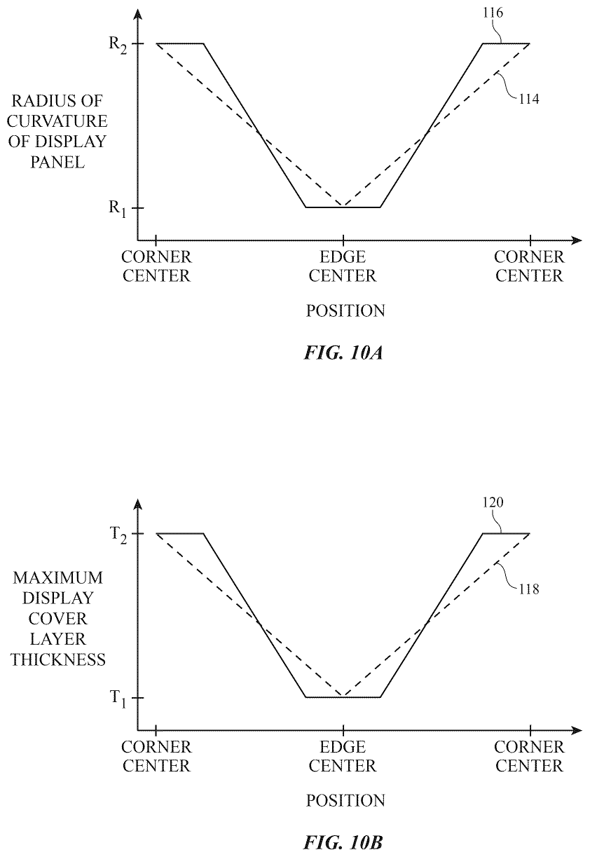

FIG. 10A is a graph of the radius of curvature of the display panel along the perimeter of the display panel as a function of position along the perimeter of the display panel. In particular, the graph shows the radius of curvature along the perimeter from one corner to another (e.g., from the middle of corner portion C1 to the middle of corner portion C2 with intervening edge portion E1, from the middle of corner portion C2 to the middle of corner portion C4 with intervening edge portion E3, from the middle of corner portion C4 to the middle of corner portion C3 with intervening edge portion E4, and/or from the middle of corner portion C3 to the middle of corner portion C1 with intervening edge portion E2). Different sides of the perimeter of the display panel may have the same radius of curvature profile or different sides of the perimeter of the display panel may have different radius of curvature profiles.

In profile 114, the radius of curvature has a minimum value R₁ at a center of the edge portion. In other words, the display panel is most curved at the center of the edge portion (e.g., as in FIG. 9A and cross-sectional line 102 of FIG. 8). The radius of curvature gradually increases from the center of the edge portion to the center of the adjacent corner portions. The radius of curvature has a maximum value R₂ at the center of the corner portions (as in FIG. 9C and cross-sectional line 106 of FIG. 8). Profile 114 shows a linear change between R₁ and both instances of R₂.

Profile 116 shows another possible example where there may be a larger portion of the perimeter of the display panel with the maximum and minimum radii of curvature. However, there is still a linear change in the radius of curvature between the portions with the maximum radius of curvature and the portion with the minimum radius of curvature similar to as with profile 114.

The profile shapes of FIG. 10A are merely illustrative. In general, the profiles may have any desired shapes (e.g., with linear portions, non-linear portions, or both).

FIG. 10B is a graph of the maximum display cover layer thickness of the display panel along the perimeter of the display as a function of position along the perimeter of the display. In particular, the graph shows the maximum display cover layer thickness along the perimeter from one corner to another (e.g., from the middle of corner portion C1 to the middle of corner portion C2 with intervening edge portion E1, from the middle of corner portion C2 to the middle of corner portion C4 with intervening edge portion E3, from the middle of corner portion C4 to the middle of corner portion C3 with intervening edge portion E4, and/or from the middle of corner portion C3 to the middle of corner portion C1 with intervening edge portion E2). Different sides of the perimeter of the display may have the same maximum display cover layer thickness profile or different sides of the perimeter of the display may have different maximum display cover layer thickness profiles.

In profile 118, the maximum display cover layer thickness has a minimum value T₁ at a center of the edge portion. In other words, the edge of the display cover layer is thinnest at the center of the edge portion (e.g., as in FIG. 9A and cross-sectional line 102 of FIG. 8). The maximum display cover layer thickness gradually increases from the center of the edge portion to the center of the adjacent corner portions. The maximum display cover layer thickness has a maximum value T₂ at the center of the corner portions (as in FIG. 9C and cross-sectional line 106 of FIG. 8). Profile 118 shows a linear change between T₁ and both instances of T₂.

Profile 120 shows another possible example where there may be a larger portion of the perimeter of the display panel with the maximum display cover layer thicknesses T₁ and T₂. However, there is still a linear change in the maximum display cover layer thickness between the portions with the maximum display cover layer thickness T₂ and the portion with the maximum display cover layer thickness T₁ similar to as with profile 118.

The profile shapes of FIG. 10B are merely illustrative. In general, the profiles may have any desired shapes (e.g., with linear portions, non-linear portions, or both).

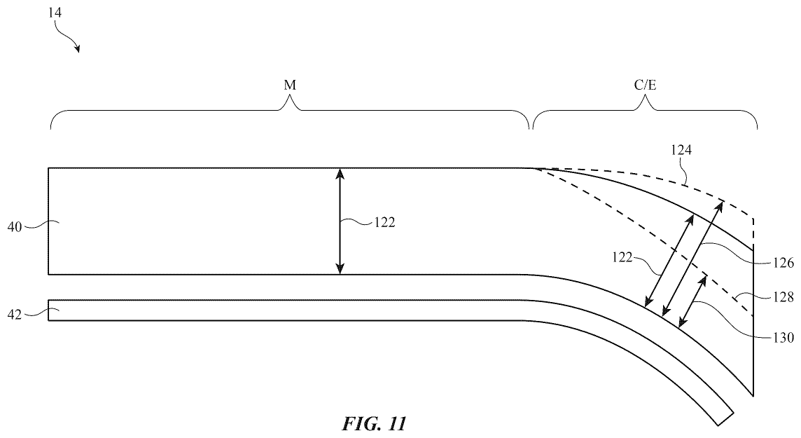

In the example of FIGS. 9 and 10, the varying thickness of the display cover layer is correlated to the varying curvature of the underlying display panel. However, this need not be the case. FIG. 11 shows another example of an illustrative display cover layer that has varying edge thickness. As shown in FIG. 11, display cover layer 40 may have a uniform thickness 122 in a planar central portion M of the display. Display cover layer 40 conforms to display panel 42 which is curved in the corner regions C and edge regions E. As shown in FIG. 11, portions of display cover layer 40 that overlap corner regions C and edge regions E may optionally have the uniform thickness 122 across the entire display panel (as indicated by the solid line at the upper surface of the display cover layer in regions C/E. Alternatively, the thickness of the display cover layer may be increased in regions C/E as indicated by dashed line 124. In this example, the display cover layer thickness 126 in regions C/E is greater than the uniform thickness 122 in central portion M. In yet another possible arrangement, the thickness of the display cover layer may be decreased in regions C/E as indicated by dashed line 128. In this example, the display cover layer thickness 130 in regions C/E is less than the uniform thickness 122 in central portion M.

When the display cover layer has an increased thickness as shown by profile 124, the thickness may vary as a function of separation from middle portion M. The thickness may gradually increase with increasing separation from middle portion M, as one example. When the display cover layer has a decreased thickness as shown by profile 128, the thickness may vary as a function of separation from middle portion M. The thickness may gradually decrease with increasing separation from middle portion M, as one example.

When the display cover layer is thickened at the edge of the display cover layer, there may be an additional lensing effect at the edge of the display to advantageously enhance a perceived three-dimensional appearance of the display. There may also desirably be increased curvature of a virtual image on display 14 when the display cover layer is thickened at the edge of the display cover layer.

A display cover layer with a thickened or thinned edge (as in FIG. 11) may be formed over a display panel with uniform curvature around its perimeter or non-uniform curvature around its perimeter (as in FIGS. 9 and 10).

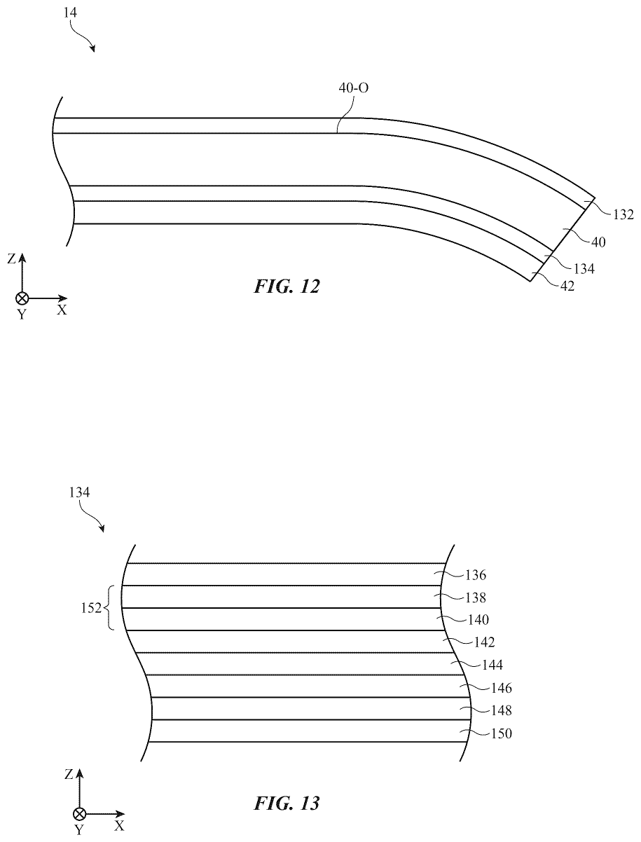

If care is not taken, reflections of ambient light off of the outer surface of display cover layer 40 and/or the outer surface of display panel 42 may reduce contrast and/or be distracting to a viewer of display 14. To mitigate reflections of ambient light, display 14 may include an anti-reflective layer and/or circular polarizer. FIG. 12 is a cross-sectional side view of an illustrative display with curved edges, an anti-reflective layer, and a circular polarizer.

As shown in FIG. 12, anti-reflective layer 132 may be formed on outer surface 40-O of display cover layer 40. The anti-reflective layer 132 may be a single-layer anti-reflective coating (ARC), a multi-layer anti-reflective coating, a moth-eye anti-reflective coating, or any other desired type of anti-reflective layer. A multi-layer anti-reflective coating may include alternating layers of material with high and low refractive indices. A moth-eye anti-reflective coating may include nanostructures (e.g., protrusions with dimensions less than the wavelength of visible light) that create an effective refractive index gradient between air and the display cover layer.

In addition to anti-reflective layer 132, display 14 may include a circular polarizer 134 between display panel 42 and display cover layer 40. FIG. 13 is a cross-sectional side view of the circular polarizer of FIG. 12. As shown in FIG. 13, the circular polarizer (sometimes referred to as a circular polarizer stack) may include a hard coat 136, a linear polarizer 152, an adhesive layer 142, a quarter wave plate 144, an adhesive layer 146, a positive C-plate 148, and an adhesive layer 150. In FIG. 13, the circular polarizer has first and second opposing sides. Hard coat 136 may be formed on the first side of the circular polarizer and adhesive layer 150 may be formed on the second side of the circular polarizer. Hard coat 136 may be formed adjacent to and optionally attached to display cover layer 40. Adhesive layer 150 may be formed adjacent to and optionally attached to display panel 42.

Hard coat 136 serves as a protective film for the circular polarizer. The linear polarizer 152 may include a polarizing layer 138 and a substrate 140. Polarizing layer 138 may be formed from poly(vinyl alcohol) (PVA) that linearly polarizes light that passes through the layer. Substrate 140 may be formed from an isotropic material such as cyclo olefin polymer (COP), tri acetate cellulose (TAC), poly(methyl methacrylate) (PMMA), or another desired material. This example of layers that form a linear polarizer is merely illustrative. In general, the linear polarizer may have any desired arrangement (e.g., multiple PVA layers separated by respective isotropic layers). Polarizing layer 138 may have a polarization efficiency that is greater than 99.96%, greater than 99.97%, greater than 99.98%, etc. Increasing the polarization efficiency of polarizing layer 138 may mitigate reflections of ambient light off display panel 42 during operation of display 14.

C-plates have an optical axis that is perpendicular to the plane of the plate (e.g., parallel to the Z-axis of FIG. 13). In a positive C-plate such as positive C-plate 148, the refractive index along the Z-axis (e.g., orthogonal to the plane of the plate) is larger than refractive indices along the X and Y axes (e.g., within the plane of the plate). In a negative C-plate, the refractive index along the Z-axis (e.g., orthogonal to the plane of the plate) is smaller than refractive indices along the X and Y axes (e.g., within the plane of the plate). In both positive C-plates (sometimes referred to as +C plates) and negative C-plates (sometimes referred to as-C plates), the refractive index along the X-axis is equal to the refractive index along the Y-axis.

Adhesive layers 142, 146, and 150 may have high transparency (e.g., greater than 80%, greater than 90%, greater than 95%, greater than 98%, greater than 99%, etc.). To mitigate reflections off display 14, adhesive layer 142 may have an index of refraction that is matched to the index of refraction of adjacent substrate layer 140 and/or adjacent quarter wave plate 144. The index of refraction of adhesive layer 142 may be 1.51, 1.52, 1.53, between (and including) 1.50 and 1.55, between (and including) 1.51 and 1.53, greater than 1.48, etc. A difference between the indices of refraction of layers 140 and 142 may be less than 0.1, less than 0.05, less than 0.03, less than 0.02, less than 0.01, etc. A difference between the indices of refraction of layers 142 and 144 may be less than 0.1, less than 0.05, less than 0.03, less than 0.02, less than 0.01, etc. Adhesive layer 142 may be formed from an ultraviolet curable adhesive material.

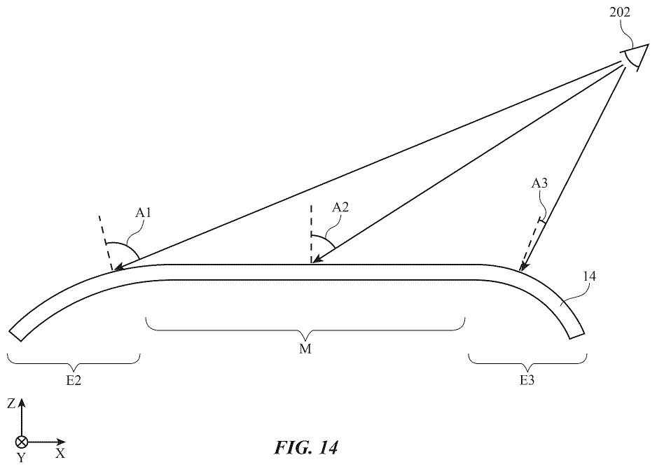

If care is not taken, the curved edges of display 14 may cause a varying luminance across the footprint of the display at off-center viewing angles. FIG. 14 is a side view of a display with curved edges illustrating this phenomenon. As shown in FIG. 14, a viewer 202 is offset from the front of display 14. Display 14 in FIG. 14 may have the same arrangement as the display of FIG. 8. In particular, display 14 has a central portion M that is interposed between edge portions E2 and E3. Central portion M, edge portion E2, and edge portion E3 are all visible to viewer 202. However, the viewing angle of each portion of the display varies.

Edge portion E2 is viewed at a viewing angle A1 relative to the surface normal of the display at the point on the display being viewed. Central portion M is viewed at a viewing angle A2 relative to the surface normal of the display at the point on the display being viewed. Edge portion E3 is viewed at a viewing angle A3 relative to the surface normal of the display at the point on the display being viewed. A1 is greater than A2 and A2 is greater than A3. In other words, the viewer is viewing on-axis light (e.g., light parallel or close to parallel to the surface normal of the display) from edge region E3, off-axis light (e.g., light far from parallel to the surface normal of the display) from edge region E2, and light at an intermediate angle from central portion M. The luminance of the display tends to decrease with increasing viewing angle relative to the surface normal of the display. Therefore, edge portion E3 may appear brighter to viewer 202 than central portion M and central portion M may appear brighter to viewer 202 than edge portion E2.

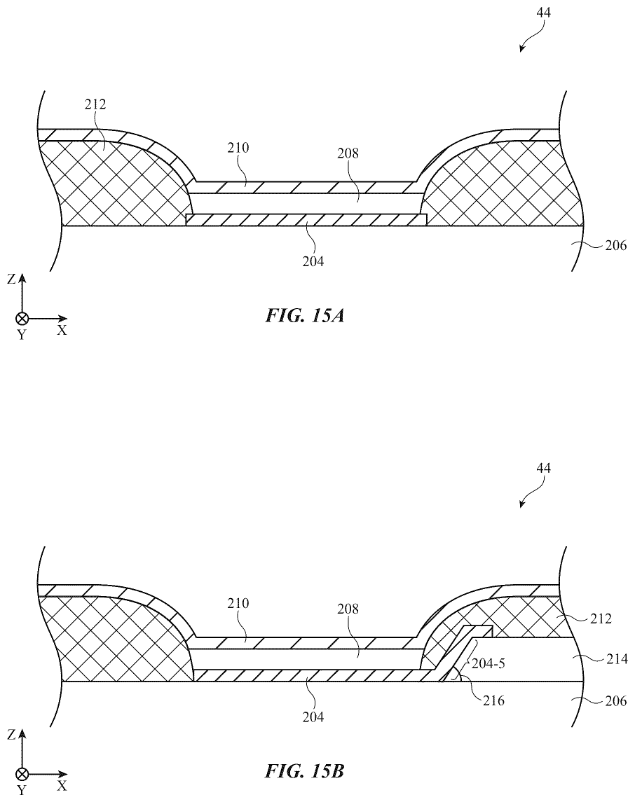

To mitigate brightness non-uniformity at the curved edges, asymmetric reflective layers may be incorporated into the pixels in the edge and corner portions of display 14. FIG. 15A is a cross-sectional side view of an illustrative display pixel 44 in central portion M of display 14. As shown in FIG. 15A, each display pixel may include an anode 204 formed on a substrate 206. Substrate 206 may be formed from glass, plastic, polymer, silicon, or any other desired material. Anode 204 may be formed from conductive material and may be covered by OLED layers 208 and cathode 210. OLED layers 208 may include one or more layers for forming an organic light-emitting diode. For example, layers 208 may include one or more of a hole-injection layer, a hole-transport layer, an emissive layer, an electron-transport layer, an electronic-injection layer, an electron blocking layer, a charge generation layer, a hole blocking layer, etc.

Cathode 210 may be a conductive layer formed on the OLED layers 208. Cathode layer 210 may form a common cathode terminal for all diodes in display 14. Cathode layer 210 may be formed from a transparent or partially transparent conductive material (e.g., indium tin oxide, a metal layer(s) that is sufficiently thin to be transparent, a combination of a thin metal and indium tin oxide, etc.). Each anode in display 14 may be independently controlled, so that each diode in display 14 can be independently controlled. This allows each pixel 44 to produce an independently controlled amount of light. Anodes 204 may sometimes be referred to as electrodes or pixel electrodes. Cathode 210 may sometimes be referred to as a common electrode.

As shown in FIG. 15A, display 14 may optionally include a pixel definition layer (PDL) 212. The pixel definition layer may be formed from a dielectric material and may be interposed between adjacent anodes of the display. The pixel definition layer may have openings in which the anodes are formed, thereby defining the light-emitting area of each pixel.

FIG. 15B is a cross-sectional side view of an illustrative display pixel 44 in an edge portion or corner portion of display 14. As shown in FIG. 15B, an additional layer 214 is formed between substrate 206 and pixel definition layer 212. Additional layer 214 may sometimes be referred to as a dielectric layer, planarization layer, etc. Layer 214 defines a surface for anode metal portion 204-S, which is used to increase efficiency/luminance for display pixel 44 at off-axis viewing angles. The metal layer that forms anode 204 and portion 204-S may have a reflectance that is greater than 70%, greater than 80%, greater than 90%, greater than 95%, etc. The metal layer that forms anode 204 and portion 204-S may comprise one or more materials such as aluminum, silver, etc.

Anode metal portion 204-S is formed on a surface of layer 214 that is at an angle 216 relative to the upper surface of substrate 206. Angle 216 may be greater than 30 degrees, greater than 45 degrees, greater than 55 degrees, greater than 65 degrees, greater than 75 degrees, greater than 85 degrees, between 45 degrees and 89 degrees, etc.

The presence of anode metal portion 204-S (sometimes referred to as side mirror portion 204-S, reflective layers 204-S, mirrors 204-S, angled mirrors 204-S, etc.) may increase the luminance of off-axis light emitted by pixel 44. In particular, the luminance of off-axis light may be increased in the direction of side mirror 204-S. For example, off-axis light in the positive X-direction relative to the surface normal in FIG. 15B has a greater luminance than off-axis light in the same direction in FIG. 15A. In contrast, off-axis light in the negative X-direction relative to the surface normal in FIG. 15B has a similar or equal luminance to off-axis light in the same direction in FIG. 15A. Each pixel in the edge and corner portions of display panel 42 may have a side mirror on the side of the pixel closer to central portion M. The side mirror for each pixel may not extend around the entire perimeter for that pixel. The side mirror for each pixel may partially but not completely surround that pixel. The side mirror for each pixel may extend around less than 60% the periphery of that pixel, less than 50% the periphery of that pixel, less than 40% the periphery of that pixel, less than 30% the periphery of that pixel, etc. With this type of arrangement, luminance non-uniformity is mitigated in display 14.

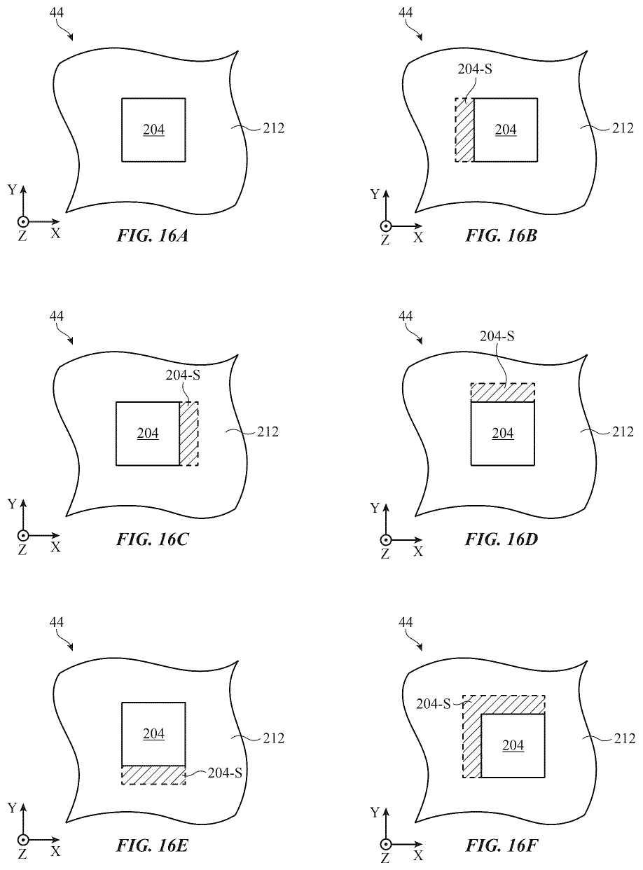

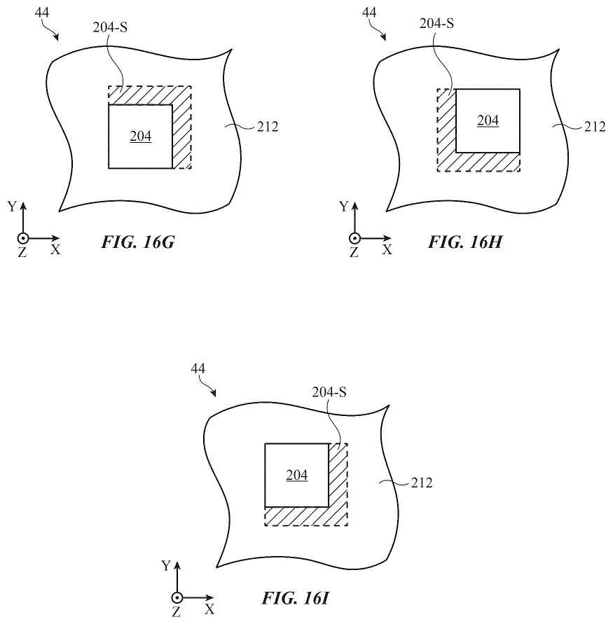

FIGS. 16A-16I are top views of pixels 44 in different portions of the display showing arrangements for side mirrors 204-S. FIG. 16A shows a pixel in central portion M of display 14 in FIG. 8. FIG. 16B shows a pixel in edge portion E3 of display 14 in FIG. 8. FIG. 16C shows a pixel in edge portion E2 of display 14 in FIG. 8. FIG. 16D shows a pixel in edge portion E4 of display 14 in FIG. 8. FIG. 16E shows a pixel in edge portion E1 of display 14 in FIG. 8. FIG. 16F shows a pixel in corner portion C4 of display 14 in FIG. 8. FIG. 16G shows a pixel in corner portion C3 of display 14 in FIG. 8. FIG. 16H shows a pixel in corner portion C2 of display 14 in FIG. 8. FIG. 16I shows a pixel in corner portion C1 of display 14 in FIG. 8.

In each one of FIGS. 16A-16I, a portion of anode 204 is exposed through the opening in pixel definition layer 212, as indicated by the solid line outlining a square. The square depicted for each pixel in FIGS. 16A-16I corresponds to the light-emitting area of that pixel.

In FIG. 16A (e.g., in central portion M), no side mirror 204-S is present. In FIG. 16B, there is a side mirror 204-S interposed between the light-emitting area and central portion M along an edge of the pixel that extends parallel to the Y-axis. However, there is no side mirror present on an opposing side of the pixel. In FIG. 16C, there is a side mirror 204-S interposed between the light-emitting area and central portion M along an edge of the pixel that extends parallel to the Y-axis. However, there is no side mirror present on an opposing side of the pixel. In FIG. 16D, there is a side mirror 204-S interposed between the light-emitting area and central portion M along an edge of the pixel that extends parallel to the X-axis. However, there is no side mirror present on an opposing side of the pixel. In FIG. 16E, there is a side mirror 204-S interposed between the light-emitting area and central portion M along an edge of the pixel that extends parallel to the X-axis. However, there is no side mirror present on an opposing side of the pixel.

In FIG. 16F, there is a side mirror 204-S interposed between the light-emitting area and central portion M along two edges of the pixel (one edge that extends parallel to the X-axis and one edge that extends parallel to the Y-axis). However, there are no side mirrors present on the opposing sides of the pixel. In FIG. 16G, there is a side mirror 204-S interposed between the light-emitting area and central portion M along two edges of the pixel (one edge that extends parallel to the X-axis and one edge that extends parallel to the Y-axis). However, there are no side mirrors present on the opposing sides of the pixel. In FIG. 16H, there is a side mirror 204-S interposed between the light-emitting area and central portion M along two edges of the pixel (one edge that extends parallel to the X-axis and one edge that extends parallel to the Y-axis). However, there are no side mirrors present on the opposing sides of the pixel. In FIG. 16I, there is a side mirror 204-S interposed between the light-emitting area and central portion M along two edges of the pixel (one edge that extends parallel to the X-axis and one edge that extends parallel to the Y-axis). However, there are no side mirrors present on the opposing sides of the pixel.

With the arrangement of FIGS. 6A-6I, off-axis luminance is asymmetrically increased (towards the direction of the side mirror) in each one of edge portions E1, E2, E3, and E4 and corner portions C1, C2, C3, and C4.

The foregoing is merely illustrative and various modifications can be made to the described embodiments. The foregoing embodiments may be implemented individually or in any combination.

What is claimed is:

1. An electronic device comprising:
a display panel comprising:
a planar central portion;
first and second opposing edge portions;
third and fourth opposing edge portions that extend between the first and second opposing edge portions, wherein each one of the first, second, third, and fourth edge portions is bent away from the planar central portion; and
an array of pixels, wherein the array of pixels comprises at least some pixels in each one of the planar central portion and the first, second, third, and fourth edge portions and wherein each one of the at least some pixels in the first, second, third, and fourth edge portions comprises a side mirror that extends around some but not all of a periphery of that pixel; and
a display cover layer that overlaps the display panel.

2. The electronic device defined in claim 1, wherein the at least some pixels in the first edge portion comprise a first pixel with a first respective side mirror and wherein the first respective side mirror is interposed between the first pixel and the planar central portion.

3. The electronic device defined in claim 2, wherein the first pixel has first and second opposing sides, wherein the first respective side mirror is formed on the first side of the first pixel, and wherein the first pixel does not include a side mirror on the second side of the first pixel.

4. The electronic device defined in claim 3, wherein the at least some pixels in the second edge portion comprise a second pixel with a second respective side mirror and wherein the second respective side mirror is interposed between the second pixel and the planar central portion.

5. The electronic device defined in claim 4, wherein the second pixel has third and fourth opposing sides, wherein the second respective side mirror is formed on the third side of the second pixel, and wherein the second pixel does not include a side mirror on the fourth side of the second pixel.

6. The electronic device defined in claim 5, wherein the at least some pixels in the third edge portion comprise a third pixel with a third respective side mirror, wherein the third respective side mirror is interposed between the third pixel and the planar central portion, wherein the at least some pixels in the fourth edge portion comprise a fourth pixel with a fourth respective side mirror, and wherein the fourth respective side mirror is interposed between the fourth pixel and the planar central portion.

7. The electronic device defined in claim 1, wherein the display panel further comprises:
a first rounded corner portion that is interposed between the first and third edge portions;
a second rounded corner portion that is interposed between the first and fourth edge portions;
a third rounded corner portion that is interposed between the second and third edge portions; and
a fourth rounded corner portion that is interposed between the second and fourth edge portions, wherein each one of the first, second, third, and fourth rounded corner portions is bent away from the planar central portion and wherein each one of the first, second, third, and fourth rounded corner portions includes at least some pixels of the array of pixels.

8. The electronic device defined in claim 7, wherein each one of the first, second, third, and fourth rounded corner portions has compound curvature.

9. The electronic device defined in claim 8, wherein the first edge portion has a radius of curvature that varies as a function of position along a perimeter of the display panel.

10. The electronic device defined in claim 9, wherein the radius of curvature is at a minimum in a middle of the first edge portion and wherein the radius of curvature increases towards the first rounded corner portion.

11. The electronic device defined in claim 9, wherein the display cover layer has a thickness that varies as a function of position along the perimeter of the display panel.

12. The electronic device defined in claim 9, wherein the display cover layer has an outer surface with bent edges and wherein the bent edges have a uniform radius of curvature around a perimeter of the display cover layer.

13. The electronic device defined in claim 7, wherein the display cover layer has a first portion that overlaps the planar central portion and a second portion that overlaps the first rounded corner portion, wherein the first portion of the display cover layer has a first thickness, and wherein the second portion of the display cover layer has a second thickness that is greater than the first thickness.

14. The electronic device defined in claim 1, wherein the display cover layer has a first portion that overlaps the planar central portion and a second portion that overlaps the first edge portion, wherein the first portion of the display cover layer has a first thickness, and wherein the second portion of the display cover layer has a second thickness that is greater than the first thickness.

15. The electronic device defined in claim 1, further comprising:
an anti-reflective layer on an outer surface of the display cover layer.

16. The electronic device defined in claim 1, further comprising:
a circular polarizer that is interposed between the display panel and the display cover layer, wherein the circular polarizer comprises a polarizing layer, a substrate, an adhesive layer, and a quarter wave plate, wherein the substrate is interposed between the polarizing layer and the adhesive layer, and wherein the adhesive layer is interposed between the substrate and the quarter wave plate.

17. The electronic device defined in claim 16, wherein the polarizing layer has a polarization efficiency of greater than 99.98%.

18. The electronic device defined in claim 16, wherein the adhesive layer has a refractive index between 1.50 and 1.55.

19. An electronic device comprising:
a display panel comprising:
a planar central portion;
first and second opposing edge portions;
third and fourth opposing edge portions that extend between the first and second opposing edge portions, wherein each one of the first, second, third, and fourth edge portions is bent away from the planar central portion;
a first rounded corner portion that is interposed between the first and third edge portions;
a second rounded corner portion that is interposed between the first and fourth edge portions;
a third rounded corner portion that is interposed between the second and third edge portions;
a fourth rounded corner portion that is interposed between the second and fourth edge portions, wherein each one of the first, second, third, and fourth rounded corner portions is bent away from the planar central portion; and
an array of pixels comprising at least some pixels in each one of the planar central portion, the first, second, third, and fourth edge portions, and the first, second, third, and fourth rounded corner portions, wherein a middle of the first edge portion has a first radius of curvature, wherein a middle of the first rounded corner portion has a second radius of curvature that is greater than the first radius of curvature, and wherein a radius of curvature of the display panel gradually increases along a perimeter of the display panel from the first radius of curvature to the second radius of curvature; and
a display cover layer that overlaps the display panel.

20. An electronic device comprising:
a display panel comprising:
a planar central portion;
first and second opposing edge portions;
third and fourth opposing edge portions that extend between the first and second opposing edge portions, wherein each one of the first, second, third, and fourth edge portions is bent away from the planar central portion; and
an array of pixels, wherein the array of pixels comprises at least some pixels in each one of the planar central portion and the first, second, third, and fourth edge portions;
a display cover layer that overlaps the display panel;
an anti-reflection layer on an outer surface of the display cover layer; and
a circular polarizer that is interposed between the display panel and the display cover layer, wherein the circular polarizer comprises a polarizing layer, a substrate, an adhesive layer, and a quarter wave plate, wherein the substrate is interposed between the polarizing layer and the adhesive layer, wherein the adhesive layer is interposed between the substrate and the quarter wave plate and wherein the adhesive layer has a refractive index between 1.50 and 1.55.
